(19) United States
(12) Patent Application Publication
(10) Pub. No.: US 2022/0055344 A1
(43) Pub. Date: Feb. 24, 2022

(54) RESIN COMPOSITION AND METAL BASE COPPER-CLAD LAMINATE

(71) Applicant: SUMITOMO BAKELITE CO., LTD., Tokyo (JP)

(72) Inventor: Daisuke Kitahara, Tokyo (JP)

(73) Assignee: SUMITOMO BAKELITE CO., LTD., Tokyo (JP)

(21) Appl. No.: 17/417,228

(22) PCT Filed: Nov. 28, 2019
(86) PCT No.: PCT/JP2019/046564

§ 371 Date: Jun. 22, 2021

(30) Foreign Application Priority Data
Dec. 26, 2018 (JP) 2018-243315

(51) Int. Cl. B32B 15/092; B32B 15/09; B32B 15/20; C08K 3/013; C08K 3/22; C08K 5/3445; C08L 63/00; C08L 71/10; C09K 5/14

(52) U.S. Cl. CPC B32B 15/092; B32B 15/09; B32B 15/20; C08K 3/013; C08K 3/22; H01L 23/36; C08L 63/00; C08L 71/10; C09K 5/14; C08K 2003/2227; C08K 5/3445

(57) ABSTRACT

A resin composition of the present invention is a resin composition used for forming a stress relaxation layer (102) of a metal base copper-clad laminate (100) configured by laminating a metal plate (101), the stress relaxation layer (102), and a piece of copper foil (103) in this order, the resin composition including: an epoxy resin having a polyether structure; a phenoxy resin; and a heat dissipation filler, in which the resin composition satisfies a characteristic of a storage elastic modulus at 25° C. being equal to or more than 0.01 GPa and equal to or less than 1.6 GPa.

### TECHNICAL FIELD

The present invention relates to a resin composition and a metal base copper-clad laminate.

### BACKGROUND ART

Until now, various developments have been made in metal base copper-clad laminates. As a technique of this kind, for example, a technique disclosed in Patent Document 1 is known. Patent Document 1 discloses a lead frame substrate with excellent heat dissipation in which a metal plate (copper), an insulating material (including a thermosetting resin, and a filler with excellent heat dissipation) , and a lead frame material (copper) are laminated in this order (Claims and FIG. 1 of Patent Document 1).

### RELATED DOCUMENT

### Patent Document

[Patent Document 1] Japanese Unexamined Patent Publication No. 2014-99574

### SUMMARY OF THE INVENTION

However, as a result of the examination by the inventors of the present invention, it has been clarified that the metal base copper-clad laminate disclosed in Patent Document 1 has room for improvement in terms of solder crack resistance and peel strength.

As a result of the further examination by the inventors of the present invention, they have found that, when using an epoxy resin having a polyether structure in combination with a phenoxy resin, a hardened material of a resin composition containing these resins has a characteristic of being able to be suitably used for a stress relaxation layer disposed between a metal plate and a piece of copper foil. As a result of further diligent research based on such findings, they have found that it is possible to improve solder crack resistance and peel strength in a metal base copper-clad laminate configured by laminating a metal plate, a stress relaxation layer, and a piece of copper foil in this order by appropriately controlling an elastic modulus in the hardened material of the resin composition. Thereby, the present invention has been completed.

According to the present invention, a resin composition which is used for forming a stress relaxation layer of a metal base copper-clad laminate configured by laminating a metal plate, the stress relaxation layer, and a piece of copper foil in this order is provided, the resin composition including:

an epoxy resin having a polyether structure;

a phenoxy resin; and

a heat dissipation filler,

in which a storage elastic modulus of a sample at 25° C. is equal to or more than 0.01 GPa and equal to or less than 1.6 GPa, where the sample is obtained by heat-treating the resin composition at 80° C. for 30 minutes and 180° C. for 60 minutes, and the storage elastic modulus is measured under conditions of a measurement temperature: −50° C. to 200° C., a temperature rising rate: 5° C./min, a frequency: 1 Hz, and tensile mode using a dynamic viscoelasticity measuring machine.

According to the present invention,

a metal base copper-clad laminate is further provided, the metal base copper-clad laminate including:

a metal plate functioning as a heat dissipation member;

a stress relaxation layer provided over the metal plate; and

a thick-film copper foil for forming a circuit provided over the stress relaxation layer,

in which the stress relaxation layer is formed from a resin layer formed of the above-described resin composition.

According to the present invention, a resin composition having excellent solder crack resistance and peel strength, and a metal base copper-clad laminate formed using the same are provided.

### BRIEF DESCRIPTION OF THE DRAWINGS

The above-mentioned objectives and other objectives, features, and advantages will be further clarified by suitable embodiments described below and accompanying drawings below.

FIG. 1 is a cross-sectional view schematically showing an example of a metal base copper-clad laminate of the present embodiment.

FIG. 2 is a cross-sectional view schematically showing an example of an electronic device of the present embodiment.

### DESCRIPTION OF EMBODIMENTS

Hereinafter, embodiments of the present invention will be described with reference to drawings. In all the drawings, same components are designated by the same reference numerals, and description thereof will not be repeated as appropriate. Furthermore, the drawings are schematic views, and dimensional ratio thereof do not match actual dimensional ratios.

An outline of a resin composition of the present embodiment will be described.

A resin composition of the present embodiment includes an epoxy resin having a polyether structure; a phenoxy resin; and a heat dissipation filler, and is used for forming a stress relaxation layer of a metal base copper-clad laminate configured by laminating a metal plate, the stress relaxation layer, and a piece of copper foil in this order.

Furthermore, the resin composition has a characteristic in which a storage elastic modulus of a sample at 25° C. is equal to or more than 0.01 GPa and equal to or less than 1.6 GPa, where the sample is obtained by heat-treating the resin composition at 80° C. for 30 minutes and 180° C. for 60 minutes, and the storage elastic modulus is measured under conditions of a measurement temperature: −50° C. to 200° C., a temperature rising rate: 5° C./min, a frequency: 1 Hz, and tensile mode using a dynamic viscoelasticity measuring machine.

According to the findings by the inventors of the present invention, it has been found that, when using an epoxy resin having a polyether structure in combination with a phenoxy resin, a hardened material of a resin composition containing these resins has a characteristic of being able to be suitably used for a stress relaxation layer disposed between a metal plate and a piece of copper foil.

In addition, by appropriately controlling an elastic modulus in the hardened material of the resin composition to be equal to or less than the above-mentioned upper limit value, it is possible to improve solder crack resistance in the metal base copper-clad laminate configured by laminating the metal plate, the stress relaxation layer, and the piece of copper foil in this order.

In the present embodiment, an upper limit value of the storage elastic modulus at 25° C. is, for example, equal to or less than 1.6 GPa, and it is preferably equal to or less than 1.5 GPa and is more preferably equal to or less than 1.0 GPa. Thereby, solder crack resistance and peel strength can be improved. Meanwhile, a lower limit value of the storage elastic modulus at 25° C. is not particularly limited, but it may be, for example, equal to or more than 0.01 GPa, and it is preferably equal to or more than 0.05 GPa and is more preferably equal to or more than 0.10 GPa. An appropriate storage elastic modulus may be selected according to linear expansion coefficients of the metal plate in the metal base copper-clad laminate.

In the present embodiment, the storage elastic modulus can be controlled by appropriately selecting, for example, the type and a formulation amount of each component contained in the resin composition, a method of preparing the resin composition, and the like. Among them, for example, the following elements are exemplified for setting the storage elastic modulus within a desired numerical value range: use of an epoxy resin having a polyether structure and a phenoxy resin; appropriate selection of the type of hardener and heat dissipation filler; adjustment of a content of these components; and the like.

According to the present embodiment, it is possible to provide a structure with excellent connection reliability in an electronic device including electronic components mounted on the metal base copper-clad laminate.

Hereinafter, the resin composition of the present embodiment will be described in detail.

The resin composition contains an epoxy resin having a polyether structure as an epoxy resin. Thereby, an elastic modulus of a hardened material of the resin composition can be reduced, and peel strength can be increased.

The above-mentioned epoxy resin having a polyether structure may contain a compound represented by General Formula (I). Since the compound represented by General Formula (I) has a polyether structure with an appropriate length, elasticity of a hardened material can be made low; and since the compound has reactive functional groups (for example, epoxy groups) at both ends, reactivity is increased, and thereby peel strength can be improved.

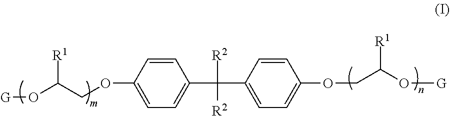

In General Formula (I), R¹ and R² each independently represent a hydrogen atom or a methyl group, and G represents a glycidyl group. m and n are each independently an integer of equal to or more than 1 and satisfy a relationship represented by 3≤(m+n)≤20.

Furthermore, it is possible to improve stress relaxation force of the metal base copper-clad laminate by incorporating the epoxy resin having a polyether structure. For example, in a case where an electronic device is manufactured, generation of defects such as cracks is inhibited at or near solder joint portions that join electronic components to the metal base copper-clad laminate even in a rapid heating/cooling environment. In this manner, heat cycle characteristics of the metal base copper-clad laminate can be improved.

The resin composition may contain another epoxy resin (A) as the epoxy resin, in addition to the epoxy resin having a polyether structure.

The epoxy resin (A) may include an epoxy resin (Al) having at least one of an aromatic ring structure and an alicyclic structure (alicyclic carbon ring structure) . By using such an epoxy resin (Al), it is possible to increase a glass transition temperature and to improve thermal conductivity of a resin layer 102.

Examples of the epoxy resin (Al) having an aromatic ring or an alicyclic structure include a bisphenol type epoxy resin such as a bisphenol A type epoxy resin, a bisphenol F type epoxy resin, a bisphenol S type epoxy resin, a bisphenol E type epoxy resin, a bisphenol M type epoxy resin, a bisphenol P type epoxy resin, and a bisphenol Z type epoxy resin; a novolac type epoxy resin such as a phenol novolac type epoxy resin, a cresol novolac type epoxy resin, and a tetraphenol group ethane type novolac type epoxy resin; an arylalkylene type epoxy resin such as a biphenyl type epoxy resin and a phenol aralkyl type epoxy resin having a biphenylene skeleton; an epoxy resin such as a naphthalene type epoxy resin; and the like. Among them, one kind thereof can be used alone, or two or more kinds thereof can be used in combination.

In addition, the resin composition may contain a liquid epoxy resin as the epoxy resin.

The liquid epoxy resin can allow a sheet to exhibit flexibility when the resin composition is B-staged.

As the liquid epoxy resin, it is possible to use an epoxy compound which has two or more epoxy groups and is in a liquid state at room temperature of 25° C.

The liquid epoxy resin may include, for example, one or more selected from the group consisting of bisphenol A diglycidyl ether, bisphenol F diglycidyl ether, alkyl diglycidyl ether, and alicyclic epoxy. Furthermore, as the liquid epoxy resin, the above-mentioned epoxy resin having a polyether structure may be used. Among them, one kind may be used alone, or two or more kinds may be used in combination.

A lower limit value of an epoxy equivalent of the liquid epoxy resin is, for example, equal to or more than 200 g, and it is preferably equal to or more than 300 g/eq and is more preferably equal to or more than 350 g/eq. An upper limit value of an epoxy equivalent of the liquid epoxy resin is not particularly limited, but it may be, for example, equal to or less than 700 g/eq.

A content of the above-mentioned epoxy resin having a polyether structure is, for example, 5 mass % to 50 mass %, and it is preferably 10 mass % to 45 mass % and is more preferably 15 mass % to 40 mass %, with respect to 100 mass % of a total solid content of the resin composition excluding the heat dissipation filler. By setting a content of the epoxy resin having a polyether structure to be equal to or more than the above lower limit value, it is possible to improve peel strength while reducing an elastic modulus of a hardened material. Furthermore, by setting a content of the epoxy resin having a polyether structure to be equal to or less than the above upper limit value, it is possible to achieve a balance with other characteristics.

A content of the epoxy resin is, for example, 20 mass % to 65 mass %, and it is preferably 25 mass % to 60 mass % and is more preferably 30 mass % to 60 mass %, with respect to 100 mass % of a total solid content of the resin composition excluding the heat dissipation filler.

The resin composition may contain the epoxy resin having a polyether structure and the liquid epoxy resin as the epoxy resin. In this case, a content of the epoxy resin having a polyether structure/a content of the liquid epoxy resin in the resin composition is 0.8 to 4.0, and it is preferably 0.9 to 3.5 and is more preferably 1.0 to 3.0. When contents are within such a range, it is possible to achieve a balance between coatability of the resin composition and low elasticity of as a film.

In the present embodiment, a solid content of the resin composition refers to a non-volatile-matter content in the resin composition, and refers to the remainder excluding volatile components such as water and a solvent. A content of the resin composition with respect to a total solid content refers to a content of a resin composition, excluding a solvent when the solvent is contained, with respect to a total solid content (100 mass %).

The resin composition contains the heat dissipation filler. Thereby, thermal conductivity of a hardened material can be improved.

As the heat dissipation filler, a known filler having excellent thermal conductivity can be used, and examples thereof include alumina. Among them, one kind may be used alone, or two or more kinds may be used in combination.

Alumina may have two or more components having different average particle sizes. For example, alumina may be a mixed system of three components (with a large particle size, a medium particle size, and a small particle size) having different average particle sizes, where a large particle size component may be spherical, and a medium particle size component and a small particle size component may be polyhedral.

Alumina may contain a large particle size alumina in which an average particle size belongs to a first particle size range of equal to or more than 5.0 μm and equal to or less than 50 μm, preferably equal to or more than 5.0 μm and equal to or less than 25 μm, and in which a circularity is equal to or more than 0.80 and equal to or less than 1.0, preferably equal to or more than 0.85 and equal to or less than 0.95.

Furthermore, alumina may contain a medium particle size alumina in which an average particle size belongs to a second particle size range of equal to or more than 1.0 μm and less than 5.0 μm, and in which a circularity is equal to or more than 0.50 and equal to or less than 0.90, preferably equal to or more than 0.70 and equal to or less than 0.80.

Furthermore, alumina may contain a small particle size alumina in which an average particle size belongs to a third particle size range of equal to or more than 0.1 μm and less than 1.0 μm, and in which a circularity is equal to or more than 0.50 and equal to or less than 0.90, preferably equal to or more than 0.70 and equal to or less than 0.80.

A particle size can be measured by subjecting alumina to an ultrasonic treatment in water for 1 minute and thereby dispersing it using a laser diffraction type particle size distribution measuring device SALD-7000.

By using alumina having an appropriate particle size, filling properties of alumina can be enhanced, and thereby a contact area between alumina particles can be further increased. As a result, thermal conductivity of a hardened material can be further improved. Furthermore, solder heat resistance, bending resistance, and insulation properties of a hardened material can be further improved. Furthermore, by using such alumina, adhesiveness between the stress resin layer and the metal plate can be further improved. According to these synergistic effects, insulation reliability of the metal base copper-clad laminate can be further enhanced.

A content of the heat dissipation filler (or alumina) is, for example, equal to or more than 40 vol % and equal to or less than 85 vol %, and it is preferably equal to or more than 45 vol % and equal to or less than 80 vol %, and is more preferably equal to or more than 55 vol % and equal to or less than 75 vol %, with respect to 100 vol % of the resin composition. By setting a content of the heat dissipation filler to be equal to or more than the above lower limit value, thermal conductivity of a hardened material can be enhanced, and thereby it is possible to realize an electronic device having excellent heat dissipation properties. Meanwhile, by setting a content of the heat dissipation filler to be equal to or less than the upper limit value, it is possible to achieve a balance with other characteristics. In addition, manufacturing stability can be improved.

The resin composition contains a phenoxy resin. Bending resistance of a hardened material can be improved by incorporating a phenoxy resin, and thereby it is possible to inhibit a deterioration in handleability due to a high degree of filling of alumina.

Examples of phenoxy resins include a phenoxy resin having a bisphenol skeleton, a phenoxy resin having a naphthalene skeleton, a phenoxy resin having an anthracene skeleton, a phenoxy resin having a biphenyl skeleton, and the like. Furthermore, it is also possible to use a phenoxy resin having a structure having a plurality of types of these skeletons.

Among them, it is preferable to use a bisphenol A type or bisphenol F type phenoxy resin. A phenoxy resin having both a bisphenol A skeleton and a bisphenol F skeleton may be used.

A weight-average molecular weight of the phenoxy resin is not particularly limited, but it is preferably equal to or more than 4.0×10⁴ and equal to or less than 8.0×10⁴.

A weight-average molecular weight of the phenoxy resin is a value in terms of polystyrene measured by gel permeation chromatography (GPC).

A content of the phenoxy resin is, for example, 15 mass % to 60 mass %, and it is preferably 18 mass % to 55 mass % and is more preferably 20 mass % to 50 mass %, with respect to 100 mass % of a total solid content of the resin composition excluding the heat dissipation filler.

A content of the epoxy resin having a polyether structure/a content of the phenoxy resin in the resin composition is 0.7 to 4.0, and it is preferably 0.8 to 3.0 and is more preferably 0.9 to 2.5. When contents are within such a range, stress relaxation force of a film made of the resin composition can be made appropriate, and thereby it is possible to enhance solder crack resistance, peel strength, and insulation reliability.

The resin composition may contain a hardener.

Examples of hardeners (hardening catalyst) include organometallic salts such as zinc naphthenate, cobalt naphthenate, tin octylate, cobalt octylate, cobalt(II) bisacetylacetonate, and cobalt(III) trisacetylacetonate; amine-based hardeners such as dicyandiamide, diethylenetriamine, triethylenetetramine, m-xylylenediamine, diaminodiphenylmethane, diaminodiethyldiphenylmethane, metaphenylenediamine, diaminodiphenyl sulfone, isophorone diamine, norbornene diamine, triethylamine, tributylamine, and diazabicyclo[2,2,2]octane; imidazole-based hardeners such as 2-phenyl-imidazole, 2-phenyl-4-methylimidazole, 2-ethyl-4-methylimidazole, 2-ethyl-4-ethylimidazole, 2-phenyl-4-methyl-5-hydroxyimidazole, and 2-phenyl-4,5-dihydroxyimidazole; organophosphorus compounds such triphenylphosphine, tri-p-tolylphosphine, tetraphenylphosphonium-tetraphenylborate, triphenylphosphine-triphenylborane, and 1,2-bis-(diphenylphosphino)ethane; phenolic compounds such as phenol, bisphenol A, and nonyiphenol; organic acids such as acetic acid, benzoic acid, salicylic acid, and p-toluenesulfonic acid; or mixtures thereof. As the hardener, one kind, including derivatives of the examples, can be used alone, or two or more kinds, including derivatives of the examples, can be used in combination.

Among them, amine-based hardeners and imidazole-based hardeners are preferable from the viewpoint that then, it is possible to obtain a hardened material having excellent adhesiveness, reacting at a relatively low temperature, and having excellent heat resistance; and imidazole-based hardeners are preferable from the viewpoint of low elasticity.

A content of the hardening catalyst is not particularly limited, but it is, for example, equal to or more than 0.05 mass % and equal to or less than 3.0 mass % with respect to 100 mass % of a total solid content of the resin composition.

The resin composition may contain a coupling agent. The coupling agent can improve wettability of an interface between an epoxy resin and alumina.

As the coupling agent, any commonly used coupling agent can be used, but specifically, it is preferable to use one or more coupling agents selected from an epoxy silane coupling agent, a cationic silane coupling agent, an aminosilane coupling agent, a titanate-based coupling agent, and a silicone oil type coupling agent.

An amount of the coupling agent added depends on a specific surface area of alumina and is not particularly limited, but it is preferably equal to or more than 0.05 parts by mass and equal to or less than 3 parts by mass, and is particularly preferably equal to or more than 0.1 parts by mass and equal to or less than 2 parts by mass with respect to 100 parts by mass of alumina.

The resin composition may contain other components as long as the effects of the present invention are not impaired. Examples of other components include antioxidants, leveling agents, and the like.

Next, a metal base copper-clad laminate 100 will be described.

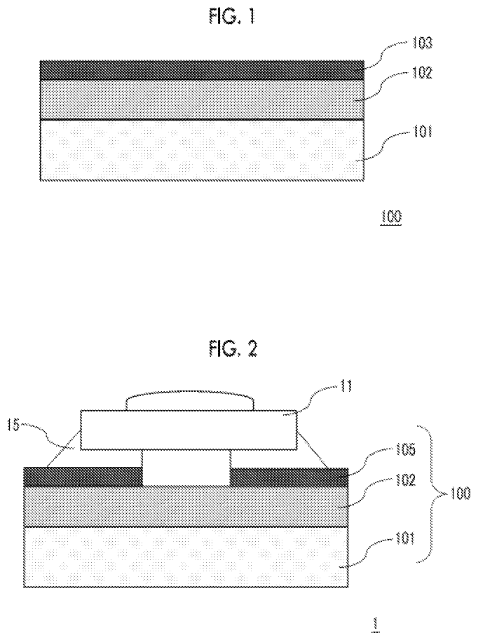

FIG. 1 is a cross-sectional view schematically showing an example of the metal base copper-clad laminate 100.

The metal base copper-clad laminate 100 of FIG. 1 includes a metal plate 101, a resin layer 102, and a metal layer 103. The metal plate 101, the resin layer 102, and the metal layer 103 configure a lamination structure in which they are laminated in this order. The metal plate 101 functions as a heat dissipation member. The resin layer 102 is a stress relaxation layer. The metal layer 103 is used for forming circuit formation.

The metal plate 101 is a plate-like member made of a metal material containing Ag or Cu as a main component. The main component means that a content ratio thereof in the metal material is, for example, equal to or more than 80 mass %, and it is more preferably equal to or more than 85 mass % . The metal plate 101 may be a plate-like substrate made of metal, or may be a plate-like substrate made of another semiconductor element or an alloy containing a metal element. As the other semiconductor elements or metal elements, for example, Si, Fe, Cu, Mn, Mg, Cr, Zn, Ti, or the like may be contained. Among them, one kind may be used alone, or two or more kinds may be used in combination.

Among them, for the metal plate 101, an aluminum plate or an alloy aluminum plate can be used from the viewpoint of a lighter weight and lower cost than a copper substrate.

It is sufficient for a thickness of the metal plate 101 to be a thickness that allows the metal plate 101 to function as a support member as a substrate. A thickness is, for example, 0.5 mm to 3.0 mm, and it is more preferably 1.0 mm to 2.0 mm. The metal plate 101 may be configured of a single layer or a laminated body having a plurality of layers.

The resin layer 102 is formed from a resin layer made of the above-mentioned resin composition. Specifically, the resin layer 102 is formed of a hardened material of the above-mentioned resin composition.

A thickness of the resin layer 102 can be appropriately selected, and it is, for example, 30 μm to 300 μm, and it is preferably 30 μm to 200 μm and is more preferably 50 μm to 120 μm.

The metal layer 103 is formed from a piece of copper foil, more preferably a piece of thick-film copper foil. The metal layer 103 maybe formed of a metal material containing Cu as amain component, and may have other metal elements such as Al, Ni, Fe, and Sn. Among them, one kind may be used alone, or two or more kinds may be used in combination.

A thickness of the metal layer 103 is, for example, 10 μm to 80 μm, and it is preferably 15 μm to 70 μm. By thickening the metal layer 103, resistance can be reduced, and thereby it is possible to realize the metal base copper-clad laminate 100 applicable to a large current.

Next, a method for manufacturing the metal base copper-clad laminate 100 will be described.

A resin layer in a B-stage state made of the resin composition is formed on the prepared metal plate 101.

As a method of forming the resin layer, a method of applying the above-mentioned resin composition to the metal layer 103 and drying it, or a method of laminating a film-like resin layer may be used.

Subsequently, the metal plate 101 is formed on a surface of the resin layer. As a method of forming the metal plate 101, a method of subjecting the resin layer and the metal plate 101 to a pressurization and heat treatment using a press or the like may be used. In a case where the resin layer is in a B-stage state, this resin layer may be hardened during the pressurization and heat treatment.

Accordingly, the metal base copper-clad laminate 100 can be obtained.

Thereafter, a metal circuit layer 105 may be formed by etching the metal layer 103 into a predetermined pattern, and the like, as necessary. Accordingly, it is possible to obtain the metal base copper-clad laminate 100 including the metal plate 101, the resin layer 102, and the metal circuit layer 105.

The metal base copper-clad laminate 100 may have a multilayer structure in which a plurality of unit structures of the metal plate 101, the resin layer 102, and the metal circuit layer 105 are laminated.

Furthermore, the metal base copper-clad laminate 100 may include a solder resist layer for an outermost layer. The solder resist layer may have an opening that exposes an electrode part connectable to an electronic component to be described later.

Next, an electronic device 1 of the present embodiment will be described.

FIG. 2 is a cross-sectional view schematically showing an example of the electronic device 1.

The electronic device 1 of FIG. 2 includes a metal base copper-clad laminate 100, an electronic component 11 provided on the metal base copper-clad laminate 100, and a connecting part (solder 15) connecting them. The electronic device 1 may include other known members not shown in FIG. 2. For example, the electronic device 1 may include a sealing member that seals the electronic component 11.

The electronic component 11 is a semiconductor element such as a transistor and a light emitting diode (LED), and various heat generating elements such as a resistor and a capacitor. Among them, one kind may be used alone, or two or more kinds may be used in combination.

The electronic device 1 is an electronic device used for usage applications to be mounted on vehicles such as automobiles (such as hybrid automobiles, fuel cell automobiles, and electric automobiles), airplanes, and rockets; usage applications to be mounted in a narrow space such as the inside of a mobile device; and the like. The electronic device 1 is, for example, a semiconductor device such as a power semiconductor device, an LED lighting, or an inverter device.

According to the present embodiment, even when the electronic device 1 is placed in an environment in which a temperature changes drastically for a long time or repeatedly, the resin layer 102, which is a stress relaxation layer, can stably reduce stress generated due to a difference in thermal expansion coefficient between the metal base copper-clad laminate 100 and the electronic component 11.

In a case where the metal plate 101 of the metal base copper-clad laminate 100 is formed from an aluminum plate or an alloy aluminum plate, a deviation in thermal expansion coefficient between the metal plate 101 and the electronic component 11 in the aluminum base copper-clad laminate becomes large, because aluminum is lightweight, but it has a characteristic of expanding and contracting significantly in response to environmental temperatures.

According to the examination by the inventors of the present invention, it has been clarified that the resin layer 102 is required to have higher stress relaxation characteristics as compared with a case in which a copper plate is used.

In this regard, by using a hardened material of a resin composition, which has excellent stress relaxation characteristics because of its low elastic modulus, for the resin layer 102, it is possible to inhibit generation of cracks in the solder 15 caused by a deviation (mismatch) in thermal expansion coefficient therebetween.

In addition, the resin layer 102 formed of a hardened material of the resin composition can have excellent characteristics such as peel strength, thermal conductivity, and insulation properties.

Accordingly, the metal base copper-clad laminate 100 can be suitably used for a heat dissipation circuit board on which the electronic component 11 such as an LED is mounted.

Furthermore, because the electronic device 1 has a structure in which the electronic component 11 is mounted on the metal base copper-clad laminate 100, it has excellent solder crack resistance, and it has excellent connection reliability even under a low temperature environment and a high temperature environment, or severe environments in which a temperature fluctuates from a high temperature to a low temperature.

Although the embodiments of the present invention have been described above, these embodiments are examples of the present invention, and various configurations other than the above embodiments can be adopted. Furthermore, the present invention is not limited to the above-described embodiments, and modifications, improvements, and the like within a range in which the object of the present invention can be achieved are included in the present invention.

### EXAMPLES

Hereinafter, the present invention will be described in detail with reference to examples, but the present invention is not limited to the description of these examples.

Information on raw material components shown in Table 1 is as follows.

(Phenoxy Resin)

Phenoxy resin 1: a phenoxy resin having a bisphenol F skeleton and a bisphenol A skeleton (4275 manufactured by Mitsubishi Chemical Corporation, weight-average molecular weight: 6.0×10⁴, ratio of bisphenol F skeleton to bisphenol A skeleton=75:25)

(Epoxy Resin)

Epoxy resin 1: bisphenol F type epoxy resin (830S manufactured by DIC Corporation, liquid epoxy resin, epoxy equivalent: 170 g/eq)

Epoxy resin 2: polyether type epoxy resin (EP-4005 manufactured by ADEKA Corporation, liquid at 25° C., viscosity: 0.8 Pa·s, epoxy equivalent: 510 g/eq)

Epoxy resin 3: acrylic resin having an all-acrylic structure (ARUFON UG-4010 manufactured by Toagosei Co., Ltd., weight-average molecular weight: 2,900)

Epoxy resin 4: epoxidized polybutadiene containing a polybutadiene skeleton (PB3600 manufactured by DAICEL, weight-average molecular weight: 5,900)

(Hardener)

Hardener 1: imidazole (trade name: 2P4MZ, manufactured by SHIKOKU CHEMICALS CORPORATION)

Hardener 2: dicyandiamide (manufactured by Degussa)

Hardener 3: novolac type phenolic resin (trade name: PR-51470, manufactured by Sumitomo Bakelite Co., Ltd.)

(Coupling Agent)

Silane coupling agent 1: γ-glycidoxypropyltrimethoxysilane (KBM-403 manufactured by Shin-Etsu Silicone)

(Heat Dissipation Filler)

Heat dissipation filler 1: spherical alumina (average particle size: 22 μm, circularity: 0.91, AX-25 manufactured by Nippon Steel & Sumikin Materials Co., Ltd.)

Heat dissipation filler 2: polyhedral alumina (average particle size: 4 μm, circularity: 0.75, LS-210 manufactured by Nippon Light Metal Holdings Company, Ltd.)

Heat dissipation filler 3: polyhedral alumina (average particle size: 0.7 μm, circularity: 0.71, LS-250 manufactured by Nippon Light Metal Holdings Company, Ltd.)

TABLE 1

| | | | | Example | Example | Example | Comparative | Comparative | Comparative |
|---|---|---|---|---|---|---|---|---|---|
| | | | Unit | 1 | 2 | 3 | Example 1 | Example 2 | Example 3 |
| Resin | Phenoxy | Phenoxy resin 1 | Mass % | 8.1 | 6.8 | 7.9 | 7.3 | 7.2 | 7.2 |
| composition | resin | | | | | | | | |
| | Epoxy | Epoxy resin1 | | 2.7 | 2.3 | 2.6 | 2.5 | 3.6 | 3.6 |
| | resin | Epoxy resin 2 | | 7.2 | 6.0 | 7.0 | 6.5 | | |
| | | Epoxy resin 3 | | | | | | 7.2 | |
| | | Epoxy resin 4 | | | | | | | 7.2 |
| | Hardener | Hardener 1 | | 0.2 | 0.2 | 0.1 | 0.1 | 0.2 | 0.2 |
| | | Hardener 2 | | | 0.6 | | | | |
| | | Hardener 3 | | | | 1.8 | | | |
| | Coupling | Silane coupling | | 1.1 | 1.1 | 1.1 | 1.1 | 1.1 | 1.1 |
| | agent | agent 1 | | | | | | | |
| | Heat | Heat dissipation | | 56.6 | 56.5 | 56.5 | 56.5 | 56.5 | 56.5 |
| | dissipation | filler 1 with | | | | | | | |
| | filler | large particle | | | | | | | |
| | | size | | | | | | | |
| | | Heat dissipation | | 12.1 | 12.5 | 12.1 | 12.1 | 12.1 | 12.1 |
| | | filler 2 with | | | | | | | |
| | | medium particle | | | | | | | |
| | | size | | | | | | | |
| | | Heat dissipation | | 12.1 | 12.5 | 12.1 | 12.1 | 12.1 | 12.1 |
| | | filler 3 with | | | | | | | |
| | | small particle | | | | | | | |
| | | size | | | | | | | |
| | | Total | | 100 | 100 | 100.0 | 100.0 | 100.0 | 100.0 |

| | | | | | | | |
|---|---|---|---|---|---|---|---|
| Content of heat dissipation | Vol % | 57.5 | 62.5 | 57.5 | 57.5 | 57.5 | 57.5 |
| filler in resin composition | | | | | | | |

| | | | | | | | |
|---|---|---|---|---|---|---|---|
| Thermal conductivity (LF method) | W/mK | 1.9 | 2.3 | 1.9 | 1.9 | — | — |
| Storage elastic modulus (DMA) | GPa | 0.9 | 1.5 | 1.5 | 8.0 | 13.0 | 4.8 |
| AC withstanding voltage (80 μm) | kV | 4.0 | 2.8 | 5.9 | 4.3 | 1.6 | 1.6 |
| Peel strength (18 μm) | kN/m | 1.1 | 1.0 | 1.2 | 0.8 | 0.6 | 0.3 |
| A: Normal state solder heat resistance | | A | A | A | A | B | B |

<Preparation of Resin Composition>

According to a formulation ratio shown in Table 1, each component was dissolved and mixed in cyclohexanone, and stirred using a high-speed stirrer. Thereby, a varnish-like resin composition having a solid content of 80 mass % was obtained.

<Creation of Metal Base Copper-Clad Laminate>

As metal foil, a piece of copper foil having a thickness of 18 μm (GTSMP manufactured by Furukawa Circuit Foil Co., Ltd.) was used. A varnish-like resin composition was applied to a roughened surface of the piece of copper foil with a comma coater, and dried by heating at 100° C. for 3 minutes and 150° C. for 3 minutes. Thereby, a piece of resin-coated copper foil having a resin thickness of 80 μm was obtained.

The obtained piece of resin-coated copper foil and a 1.5-mm thick aluminum plate (#4045) were bonded and pressed with a vacuum press under conditions of 80° C., 30 minutes, 180° C., and 60 minutes at a press pressure of 100 kg/cm², and thereby a metal base copper-clad laminate (a thickness of an insulating resin layer: 80 μm) was obtained.

(Thermal Conductivity)

The piece of copper foil and the aluminum plate were peeled off from the metal base copper-clad laminate to obtain an insulating resin layer. Then, thermal conductivity in a thickness direction of the insulating resin layer was measured. Specifically, thermal conductivity was calculated using the following expression from a thermal diffusion coefficient (α) measured by a laser flash method (half-time method), a specific heat (Cp) measured by a DSC method, and a density (ρ) measured in accordance with JIS-K-6911. A unit of thermal conductivity is W/m·K. Thermal conductivity [W/m·K]=α[m²/s]×Cp[J/kg·K]×ρ[g/cm³]

(Storage Elastic Modulus (E′))

The piece of copper foil and the aluminum plate were peeled off from the metal base copper-clad laminate to obtain an insulating resin layer. Then, the insulating resin layer was cut to obtain a test piece of 8×20 mm. The measurement was performed in tensile mode, at a frequency of 1 Hz, and within a temperature range of −50° C. to 200° C. with a temperature rising rate of 5° C./min, by a dynamic viscoelasticity measuring device. Then, a storage elastic modulus (GPa) at 25° C. was obtained.

(Dielectric Breakdown Voltage)

The metal base copper-clad laminate was cut into 100 mm×100 mm with a grinder saw. Thereafter, the piece of copper foil was removed by etching to create a sample. Using a withstand voltage tester (MODEL 7473, manufactured by EXTECH Electronics), electrodes were brought into contact with the insulating resin layer and the aluminum plate, and an alternating voltage was applied to both electrodes so that a voltage rose at a rate of 0.5 kV/sec. A voltage at which the insulating resin layer of the metal base copper-clad laminate was broken down was defined as a dielectric breakdown voltage (kV).

(Peel Strength)

The metal base copper-clad laminate was cut to 100 mm×25 mm with a grinder saw. Thereafter, a sample was produced by etching so that only 100 mm×10 mm of the piece of copper foil was left in the center, and peel strength (kN/m) at 23° C. between the piece of copper foil and the insulating resin layer was measured. The peel strength was measured in accordance with JIS C 6481.

(Solder Heat Resistance)

The metal base copper-clad laminate was cut to 50 mm×50 mm with a grinder saw. Thereafter, a sample was produced by etching so that only a half of the piece of copper foil was left, and evaluated in accordance with JIS C 6481. For the evaluation, the sample was immersed in a solder bath at 260° C. for 30 seconds, and thereafter the presence or absence of abnormalities in appearance was examined.

Evaluation Criteria

A: no abnormality

B: abnormality (locations with swelling in the entire sample)

It was found that the resin compositions of Examples 1 to 3 had high thermal conductivity and could be made to have low elasticity as compared with Comparative Examples 1 to 3, and thereby, it was possible to realize a metal base copper-clad laminate having high peel strength as compared with Comparative Examples 1 to 3, and having excellent solder crack resistance and insulation reliability as compared with Comparative Examples 2 and 3. Such a metal base copper-clad laminate can be suitably used for a heat dissipation circuit board on which an electronic component such as an LED is mounted.

This application claims priority on the basis of Japanese Patent Application No. 2018-243315 filed Dec. 26, 2018, the entire disclosure of which is incorporated herein by reference.

1. A resin composition which is used for forming a stress relaxation layer of a metal base copper-clad laminate configured by laminating a metal plate, the stress relaxation layer, and a piece of copper foil in this order, the resin composition comprising:
an epoxy resin having a polyether structure;
a phenoxy resin; and
a heat dissipation filler,
wherein a storage elastic modulus of a sample at 25° C. is equal to or more than 0.01 GPa and equal to or less than 1.6 GPa, where the sample is obtained by heat-treating the resin composition at 80° C. for 30 minutes and 180° C. for 60 minutes, and the storage elastic modulus is measured under conditions of a measurement temperature: −50° C. to 200° C., a temperature rising rate: 5° C./min, a frequency: 1 Hz, and tensile mode using a dynamic viscoelasticity measuring machine.

2. The resin composition according to claim 1,
wherein the epoxy resin haying a polyether structure contains a compound represented by General Formula (I): 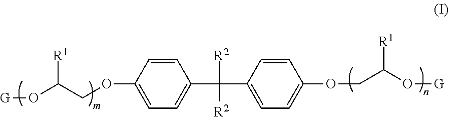
(in General Formula (I), R¹ and R² each independently represent a hydrogen atom or a methyl group, G represents a glycidyl group, and m and n are each independently an integer of equal to or more than 1 and satisfy a relationship represented by 3≤(m+n)≤20).

3. The resin composition according to claim 1, comprising:
a hardener.

4. The resin composition according to claim 3,
wherein the hardener includes an imidazole-based hardener.

5. The resin composition according to claim 1,
wherein the heat dissipation filler includes alumina.

6. The resin composition according to claim 5,
wherein the alumina includes two or more kinds having different average particle sizes.

7. The resin composition according to claim 1,
wherein a content of the heat dissipation filler is equal to or more than 40 vol % and equal to or less than 85 vol % with respect to 100 vol % of the resin composition.

8. The resin composition according to claim 1, comprising:
a liquid epoxy resin.

9. The resin composition according to claim 1,
wherein the metal plate is an aluminum substrate.

10. A metal base copper-clad laminate comprising:
a metal plate functioning as a heat dissipation member;
a stress relaxation layer provided over the metal plate; and
a thick-film copper foil for forming a circuit provided over the stress relaxation layer, wherein the stress relaxation layer is formed from a resin layer formed of the resin composition according to claim 1.
